(19) United States
(12) Patent Application Publication
(10) Pub. No.: US 2025/0118631 A1
(43) Pub. Date: Apr. 10, 2025

(54) SEMICONDUCTOR STRUCTURE AND METHOD FOR FABRICATING THE SAME

(71) Applicant: Winbond Electronics Corp., Taichung City (TW)

(72) Inventor: Jin-Neng WU, Kaohsiung City (TW)

(73) Assignee: Winbond Electronics Corp., Taichung City (TW)

(21) Appl. No.: 18/424,400

(22) Filed: Jan. 26, 2024

(30) Foreign Application Priority Data
Oct. 6, 2023 (TW) 112138482

(51) Int. Cl. H01L 23/48; H01L 21/768; H01L 23/00; H01L 23/522; H01L 23/532; H01L 25/10

(52) U.S. Cl. CPC H01L 23/481; H01L 21/76898; H01L 23/5226; H01L 23/53228; H01L 24/14; H01L 24/16; H01L 25/105; H10D 1/68; H01L 2224/14181; H01L 2224/16145

(57) ABSTRACT

A semiconductor structure is provided. The semiconductor structure includes a substrate, a BEOL layer, a plurality of first metal structures and a plurality of second metal structures. The substrate has a first side and a second side opposite to the first side. The BEOL layer is disposed on the first side of the substrate. The first metal structures penetrate the substrate. The second metal structures are disposed in the substrate, extending from the second side towards the first side of the substrate, corresponding to the first metal structures.

### CROSS REFERENCE TO RELATED APPLICATIONS

This Application claims priority of Taiwan Patent Application No. 112138482, filed on Oct. 6, 2023, the entirety of which is incorporated by reference herein.

### BACKGROUND OF THE INVENTION

### Field of the Invention

The present disclosure relates to a semiconductor structure, and, in particular, to a semiconductor structure containing embedded metal-insulator-metal (MIM) capacitors.

### Description of the Related Art

Semiconductor devices are widely used in various electronic products, such as personal computers, mobile phones, digital cameras, and other electronic equipment. Products applied from existing semiconductor devices are becoming smaller and smaller in size. Due to their physical characteristics, capacitors still need to take up more space, yet semiconductor devices still need to be reduced in size.

### BRIEF SUMMARY OF THE INVENTION

The present disclosure provides a semiconductor structure including a substrate, a back-end-of-line (BEOL) layer, a plurality of first metal structures and a plurality of second metal structures. The substrate has a first side and a second side opposite to the first side. The BEOL layer is disposed on the first side of the substrate. The first metal structures penetrate the substrate. The second metal structures are disposed in the substrate, extend from the second side towards the first side of the substrate, and correspond to the first metal structures.

The present disclosure provides a semiconductor structure including a first semiconductor unit and a second semiconductor unit. The second semiconductor unit is electrically connected to the first semiconductor unit. The first semiconductor unit includes a first substrate, a first BEOL layer, a plurality of first metal structures and a plurality of second metal structures. The first substrate has a first side and a second side opposite to the first side. The first BEOL layer is disposed on the first side of the first substrate. The first metal structures penetrate the first substrate. The second metal structures are disposed in the first substrate, extend from the second side towards the first side of the first substrate, and correspond to the first metal structures. The second semiconductor unit includes a second substrate, a second BEOL layer, a plurality of third metal structures and a plurality of fourth metal structures. The second substrate has a first side and a second side opposite to the first side. The second BEOL layer is disposed on the first side of the second substrate. The third metal structures penetrate the second substrate. The fourth metal structures are disposed in the second substrate, extend from the second side towards the first side of the second substrate, and correspond to the third metal structures.

The present disclosure provides a method for fabricating a semiconductor structure including the following steps. A carrier with a substrate is provided. The substrate has a first side and a second side opposite to the first side. A BEOL layer is disposed on the first side of the substrate. A plurality of first metal structures penetrate the substrate. Next, a plurality of vias are disposed in the substrate. The vias extend from the second side towards the first side of the substrate, and correspond to the first metal structures. Next, metal is filled into the vias to form a plurality of second metal structures.

### BRIEF DESCRIPTION OF THE DRAWINGS

FIGS. 1, 3 and 4 show top views of a semiconductor structure according to one embodiment of the present disclosure;

FIGS. 2 and 5 show cross-sectional views of a semiconductor structure according to one embodiment of the present disclosure;

FIGS. 6A-6H show cross-sectional views of a method for fabricating a semiconductor structure according to one embodiment of the present disclosure.

### DETAILED DESCRIPTION OF THE INVENTION

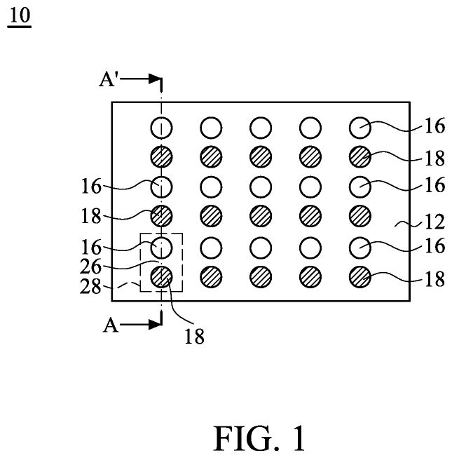

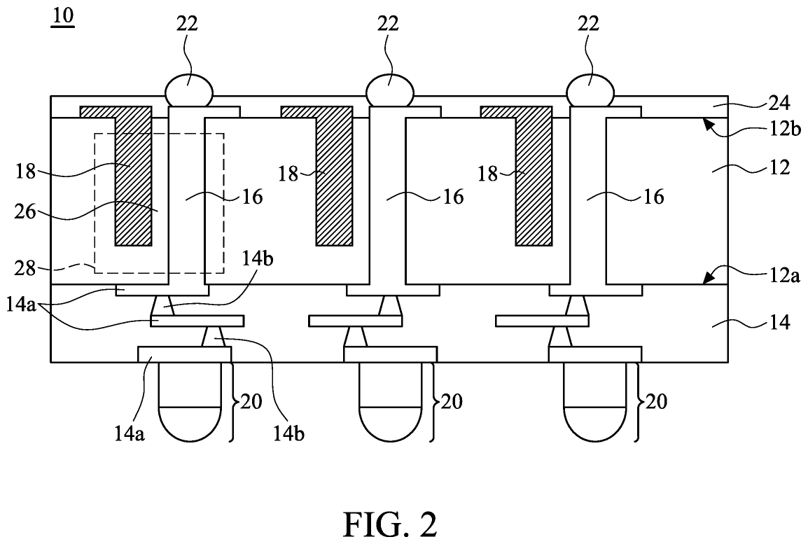

FIG. 1 is a top view of a semiconductor structure 10 according to one embodiment of the present disclosure. FIG. 2 is a cross-sectional view taken along the A-A′ cross-sectional line in FIG. 1. Referring to FIGS. 1 and 2, the semiconductor structure 10 includes a substrate 12, a back-end-of-line (BEOL) layer 14, a plurality of metal structures 16 and a plurality of metal structures 18. The substrate 12 has a first side 12a and a second side 12b opposite to the first side 12a. The BEOL layer 14 is disposed on the first side 12a of the substrate 12. The metal structures 16 penetrate the substrate 12. The metal structures 18 is disposed in the substrate 12, extend from the second side 12b towards the first side 12a of the substrate 12, and correspond to the metal structures 16. In the present disclosure, the arrangement of the metal structures 16 and the metal structures 18 may include different corresponding manners, which will be described in detail later.

In one embodiment, the substrate 12 may include a rigid substrate or a flexible substrate. The rigid substrate may include, for example, a silicon substrate or a glass substrate, but the present disclosure is not limited thereto. The flexible substrate may include, for example, a polyimide (PI) substrate, a polyethylene terephthalate (PET) substrate, or a polycarbonate (PC) substrate, but the present disclosure is not limited thereto.

In one embodiment, the BEOL layer 14 may include a plurality of metal layers 14a. The metal layers 14a of different layers are connected by vias 14b filled with metal materials. In one embodiment, copper may be selected as the metal material to fill the vias 14b.

In one embodiment, the metal structures 16 and the metal structures 18 may include copper or other suitable metal conductive materials. In one embodiment, in the metal structure 16 and the metal structure 18, an oxide material layer as an insulating layer and a tantalum (Ta) metal layer as a seed layer may be further included between the filled metal conductive material and the substrate 12 to facilitate subsequent steps, such as, filling of copper metal layer. In one embodiment, the metal structures 16 and the metal structures 18 may include columnar structures, for example, cylindrical structures or other columnar structures of any shape. In the present disclosure, the metal structures 16 may be called frontside through-silicon-vias (TSVs). The metal structures 18 may be called backside TSVs.

In one embodiment, the corresponding manners in which the metal structures 16 and the metal structures 18 are arranged may include a single metal structure 16 corresponding to a single metal structure 18, as shown in FIGS. 1 and 2. That is, a single frontside through-silicon-via (TSV) corresponds to a single backside TSV.

In one embodiment, the semiconductor structure 10 further includes a plurality of bumps 20, a plurality of bumps 22, and a redistribution layer (RDL) 24, as shown in FIG. 2. The bumps 20 are disposed on the BEOL layer 14. The bumps 22 are disposed on the metal structures 16. The redistribution layer 24 is disposed on the second side 12b of the substrate 12 to cover the metal structures 16 and the metal structures 18, exposing the bumps 22. In FIG. 2, the bumps 20, the BEOL layer 14, the metal structures 16, and the bumps 22 form conductive paths that can electrically connect the semiconductor structure 10 to other semiconductor structures.

In one embodiment, one of the metal structures 16, one of the metal structures 18, and a partial area 26 of the substrate 12 between the metal structure 16 and the metal structure 18 form a single metal-insulator-metal (MIM) capacitor 28. In the present disclosure, the MIM capacitor 28 may be an embedded MIM capacitor.

It is worth mentioning that due to the simple structure of the embodiment, the semiconductor structure 10 may easily configure hundreds to thousands of sets of MIM capacitors 28. The overall capacitance may easily reach the capacitance of a single ultra-small capacitor, for example, 0.1 pF-33 pF, which may replace traditional ultra-small capacitors.

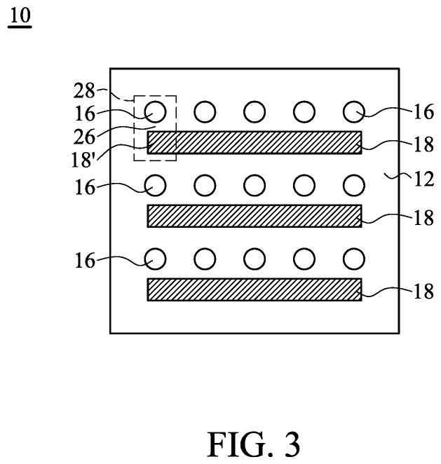

FIG. 3 is a top view of a semiconductor structure 10 according to another embodiment of the present disclosure. The embodiment in FIG. 3 is similar to the embodiments shown in FIGS. 1 and 2. The main difference lies in structural shapes and corresponding manners of the metal structures 16 and the metal structures 18. According to FIG. 3, in one embodiment, the metal structures 16 may include columnar structures, for example, cylindrical structures or other columnar structures of any shape. The metal structures 18 may include rectangular structures, such as rectangular trench structures or other columnar structures of any shape, but the present disclosure is not limited thereto, and other suitable structural shapes are also applicable to the present disclosure.

As shown in FIG. 3, in one embodiment, the corresponding manners in which the metal structures 16 and the metal structures 18 are arranged may include a plurality of metal structures 16 corresponding to one of the metal structures 18. That is, multiple frontside TSVs correspond to a single backside TSV.

In one embodiment, one of the metal structures 16, a partial structure 18′ of the metal structure 18, and a partial area 26 of the substrate 12 between the metal structure 16 and the partial structure 18′ of the metal structure 18 form a single MIM capacitor 28. In the present disclosure, the MIM capacitor 28 may be an embedded MIM capacitor.

It is worth mentioning that due to the simple structure of the embodiment, the semiconductor structure 10 may easily configure hundreds to thousands of sets of MIM capacitors 28. The overall capacitance may easily reach the capacitance of a single ultra-small capacitor, for example, 0.1 pF-33 pF, which may replace traditional ultra-small capacitors.

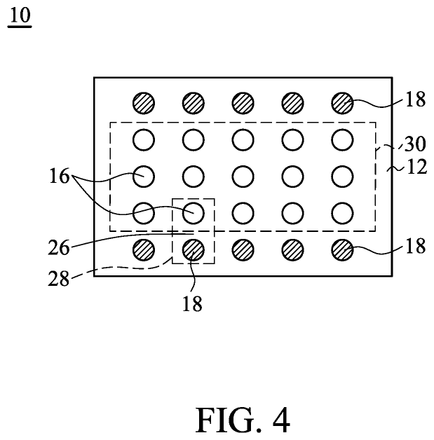

FIG. 4 is a top view of a semiconductor structure 10 according to another embodiment of the present disclosure. The embodiment in FIG. 4 is similar to the embodiments shown in FIGS. 1 and 2. The main difference lies in corresponding manners of the metal structures 16 and the metal structures 18.

As shown in FIG. 4, in one embodiment, the corresponding manner of the metal structures 16 and the metal structures 18 is as follows. The metal structures 16 are arranged to form an array 30, and the metal structures 18 are arranged on both sides of the array 30. That is, a single frontside TSV located at the edge of the array 30 corresponds to a single backside TSV.

In one embodiment, one of the metal structures 16, one of the metal structures 18, and a partial area 26 of the substrate 12 between the metal structure 16 and the metal structure 18 form a single MIM capacitor 28. In the present disclosure, the MIM capacitor 28 may be an embedded MIM capacitor.

It is worth mentioning that due to the simple structure of the embodiment, the semiconductor structure 10 may easily configure hundreds to thousands of sets of MIM capacitors 28. The overall capacitance may easily reach the capacitance of a single ultra-small capacitor, for example, 0.1 pF-33 pF, which may replace traditional ultra-small capacitors.

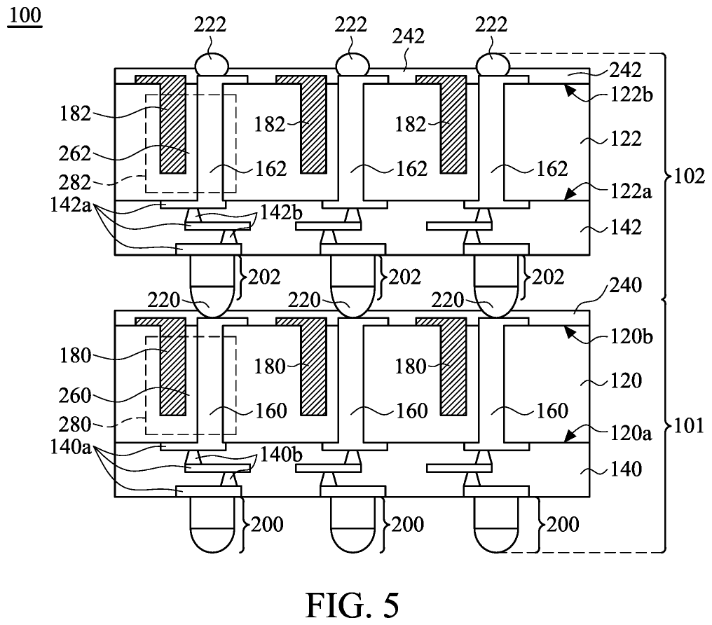

FIG. 5 is a cross-sectional view of a semiconductor structure 100 according to one embodiment of the present disclosure. Referring to FIG. 5, the semiconductor structure 100 includes a semiconductor unit 101 and a semiconductor unit 102, and the semiconductor unit 101 is electrically connected to the semiconductor unit 102.

The semiconductor unit 101 includes a substrate 120, a BEOL layer 140, a plurality of metal structures 160 and a plurality of metal structures 180. The substrate 120 has a first side 120a and a second side 120b opposite to the first side 120a. The BEOL layer 140 is disposed on the first side 120a of the substrate 120. The metal structures 160 penetrate the substrate 120. The metal structures 180 is disposed in the substrate 120, extend from the second side 120b towards the first side 120a of the substrate 120, and correspond to the metal structures 160.

In one embodiment, the substrate 120 may include a rigid substrate or a flexible substrate. The rigid substrate may include, for example, a silicon substrate or a glass substrate, but the present disclosure is not limited thereto. The flexible substrate may include, for example, a PI substrate, a PET substrate, or a PC substrate, but the present disclosure is not limited thereto.

In one embodiment, the BEOL layer 140 may include a plurality of metal layers 140a. The metal layers 140a of different layers are connected by vias 140b filled with metal materials. In one embodiment, copper may be selected as the metal material to fill the vias 140b.

In one embodiment, the metal structures 160 and the metal structures 180 may include copper or other suitable metal conductive materials. In one embodiment, in the metal structure 160 and the metal structure 180, an oxide material layer as an insulating layer and a tantalum metal layer as a seed layer may be further included between the filled metal conductive material and the substrate 120 to facilitate subsequent steps, such as, filling of copper metal layer. In one embodiment, the metal structures 160 and the metal structures 180 may include columnar structures, for example, cylindrical structures or other columnar structures of any shape. In the present disclosure, the metal structures 160 may be called frontside TSVs. The metal structures 180 may be called backside TSVs.

In one embodiment, the corresponding manners in which the metal structures 160 and the metal structures 180 are arranged may include a single metal structure 160 corresponding to a single metal structure 180, as shown in FIG. 5. That is, a single frontside TSV corresponds to a single backside TSV.

In one embodiment, the semiconductor unit 101 further includes a plurality of bumps 200, a plurality of bumps 220, and a RDL 240, as shown in FIG. 5. The bumps 200 are disposed on the BEOL layer 140. The bumps 220 are disposed on the metal structures 160. The redistribution layer 240 is disposed on the second side 120b of the substrate 120 to cover the metal structures 160 and the metal structures 180, exposing the bumps 220. In the semiconductor unit 101, the bumps 200, the BEOL layer 140, the metal structures 160, and the bumps 220 can be electrically connected to each other, so that the semiconductor unit 101 is electrically connected to other semiconductor units.

In one embodiment, one of the metal structures 160, one of the metal structures 180, and a partial area 260 of the substrate 120 between the metal structure 160 and the metal structure 180 form a single MIM capacitor 280. In the present disclosure, the MIM capacitor 280 may be an embedded MIM capacitor.

It is worth mentioning that due to the simple structure of the embodiment, the semiconductor unit 101 may easily configure hundreds to thousands of sets of MIM capacitors 280. The overall capacitance may easily reach the capacitance of a single ultra-small capacitor, for example, 0.1 pF-33 pF, which may replace traditional ultra-small capacitors.

As shown in FIG. 5, the semiconductor unit 102 includes a substrate 122, a BEOL layer 142, a plurality of metal structures 162 and a plurality of metal structures 182. The substrate 122 has a first side 122a and a second side 122b opposite to the first side 122a. The BEOL layer 142 is disposed on the first side 122a of the substrate 122. The metal structures 162 penetrate the substrate 122. The metal structures 182 is disposed in the substrate 122, extend from the second side 122b towards the first side 122a of the substrate 122, and correspond to the metal structures 162.

In one embodiment, the substrate 122 may include a rigid substrate or a flexible substrate. The rigid substrate may include, for example, a silicon substrate or a glass substrate, but the present disclosure is not limited thereto. The flexible substrate may include, for example, a PI substrate, a PET substrate, or a PC substrate, but the present disclosure is not limited thereto.

In one embodiment, the BEOL layer 142 may include a plurality of metal layers 142a. The metal layers 142a of different layers are connected by vias 142b filled with metal materials. In one embodiment, copper may be selected as the metal material to fill the vias 142b.

In one embodiment, the metal structures 162 and the metal structures 182 may include copper or other suitable metal conductive materials. In one embodiment, in the metal structure 162 and the metal structure 182, an oxide material layer as an insulating layer and a tantalum metal layer as a seed layer may be further included between the filled metal conductive material and the substrate 122 to facilitate subsequent steps, such as, filling of copper metal layer. In one embodiment, the metal structures 162 and the metal structures 182 may include columnar structures, for example, cylindrical structures or other columnar structures of any shape. In the present disclosure, the metal structures 162 may be called frontside TSVs. The metal structures 182 may be called backside TSVs.

In one embodiment, the corresponding manners in which the metal structures 162 and the metal structures 182 are arranged may include a single metal structure 162 corresponding to a single metal structure 182, as shown in FIG. 5. That is, a single frontside TSV corresponds to a single backside TSV.

In one embodiment, the semiconductor unit 102 further includes a plurality of bumps 202, a plurality of bumps 222, and a RDL 242, as shown in FIG. 5. The bumps 202 are disposed on the BEOL layer 142. The bumps 222 are disposed on the metal structures 162. The redistribution layer 242 is disposed on the second side 122b of the substrate 122 to cover the metal structures 162 and the metal structures 182, exposing the bumps 222. In the semiconductor unit 102, the bumps 202, the BEOL layer 142, the metal structures 162, and the bumps 222 form conductive paths that can electrically connect the semiconductor unit 102 to other semiconductor units.

As shown in FIG. 5, the metal structures 160 in the semiconductor unit 101 and the metal structures 162 in the semiconductor unit 102 are electrically connected through the conductive paths (bumps/metal layers/vias) in the semiconductor unit 101 and the semiconductor unit 102.

In one embodiment, one of the metal structures 162, one of the metal structures 182, and a partial area 262 of the substrate 122 between the metal structure 162 and the metal structure 182 form a single MIM capacitor 282. In the present disclosure, the MIM capacitor 282 may be an embedded MIM capacitor.

It is worth mentioning that due to the simple structure of the embodiment, the semiconductor unit 102 may easily configure hundreds to thousands of sets of MIM capacitors 282. The overall capacitance may easily reach the capacitance of a single ultra-small capacitor, for example, 0.1 pF-33 pF, which may replace traditional ultra-small capacitors.

In the present disclosure, the capacitance of the overall semiconductor structure can be expanded by connecting several upper and lower semiconductor units (capacitors) in series.

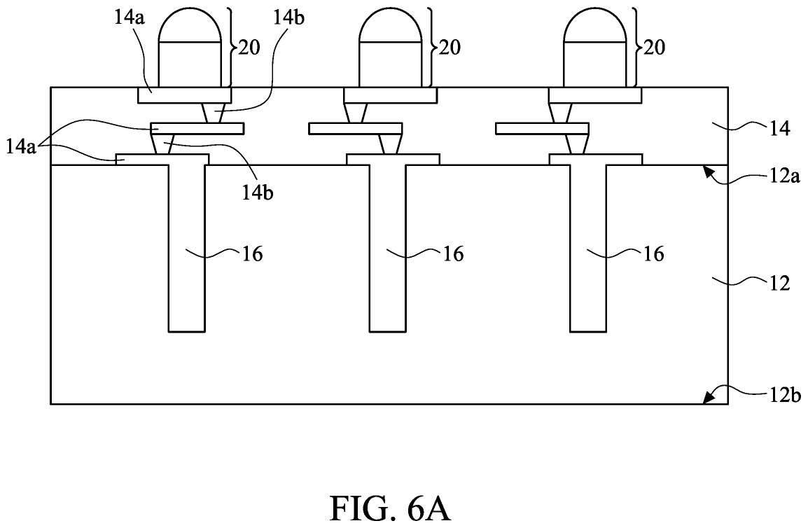

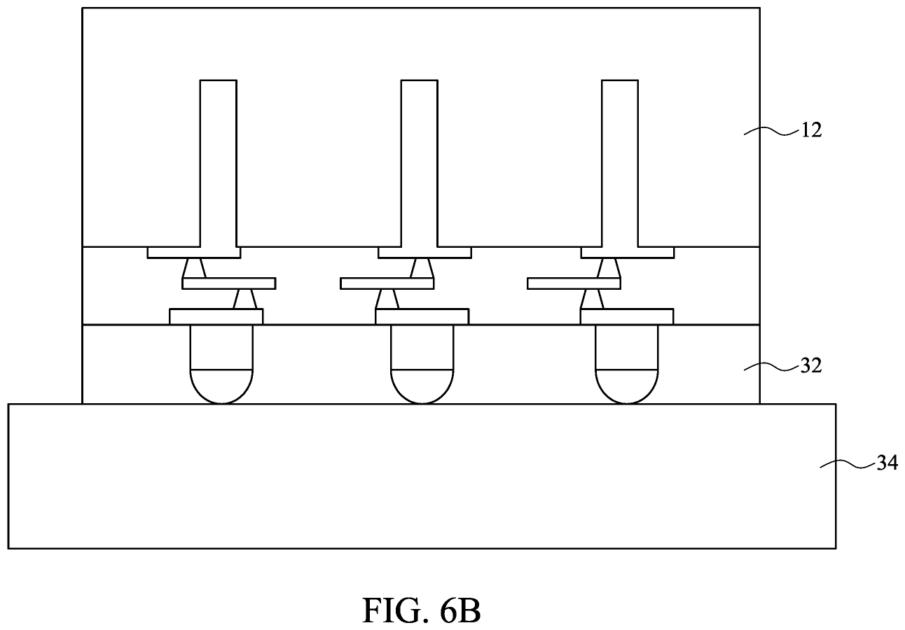

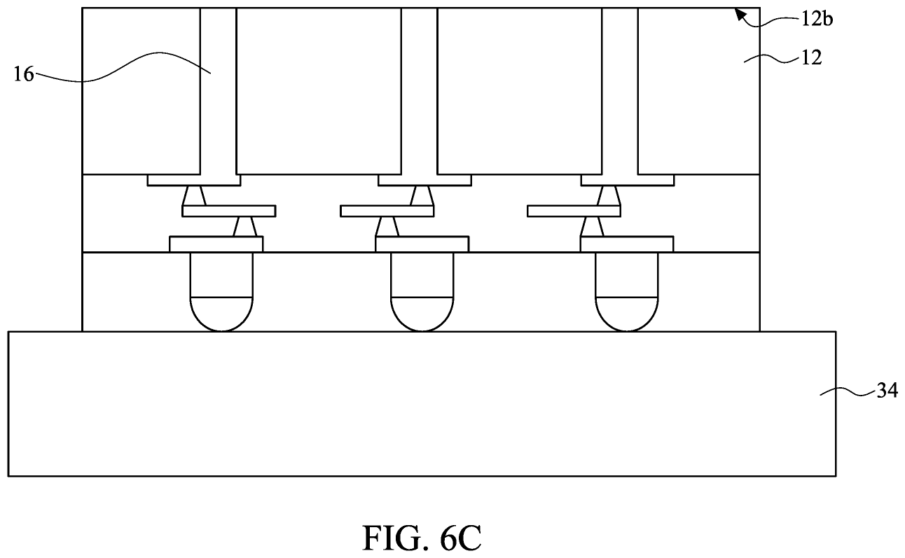

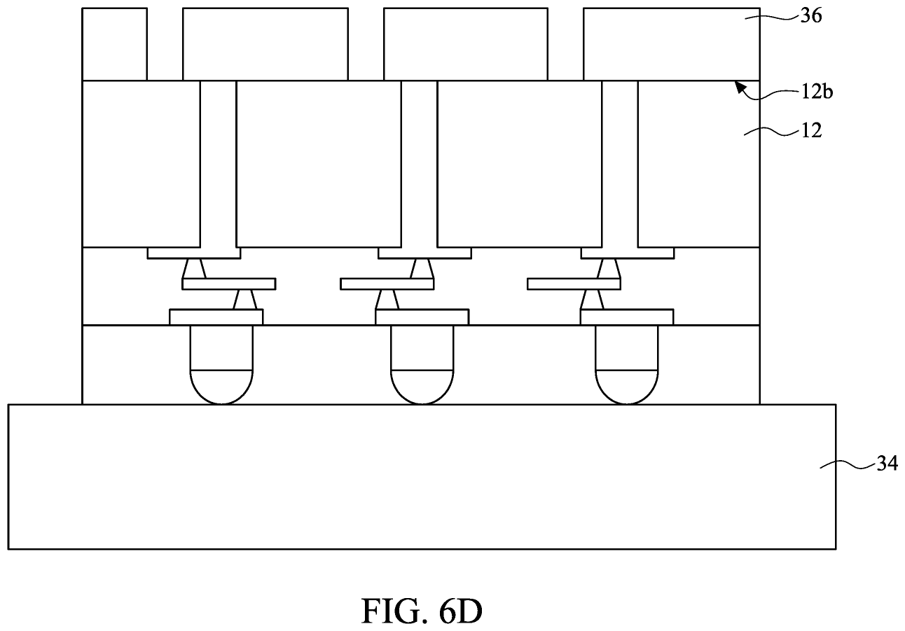

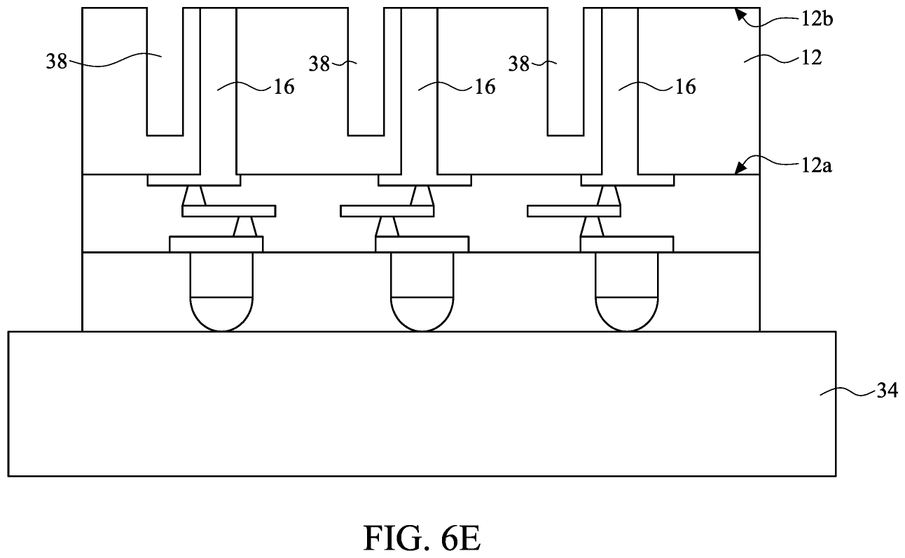

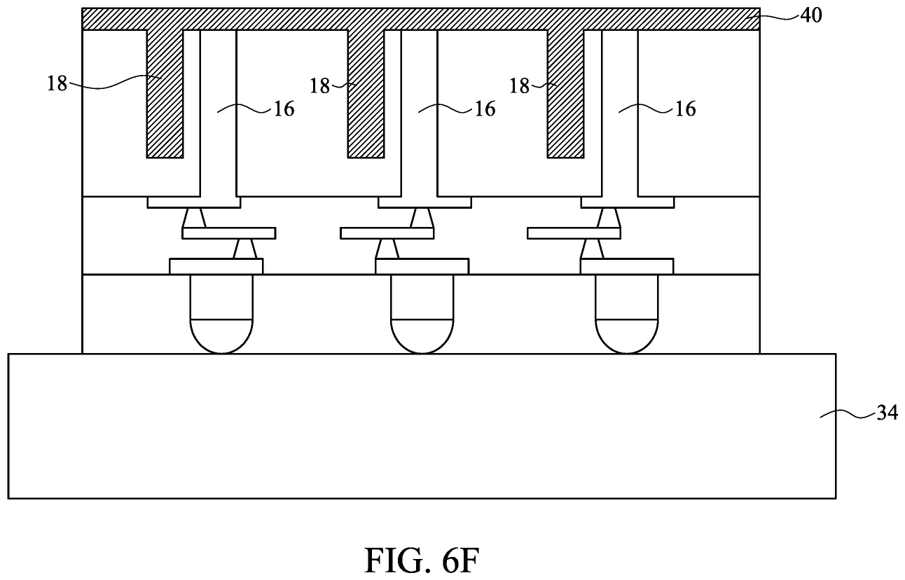

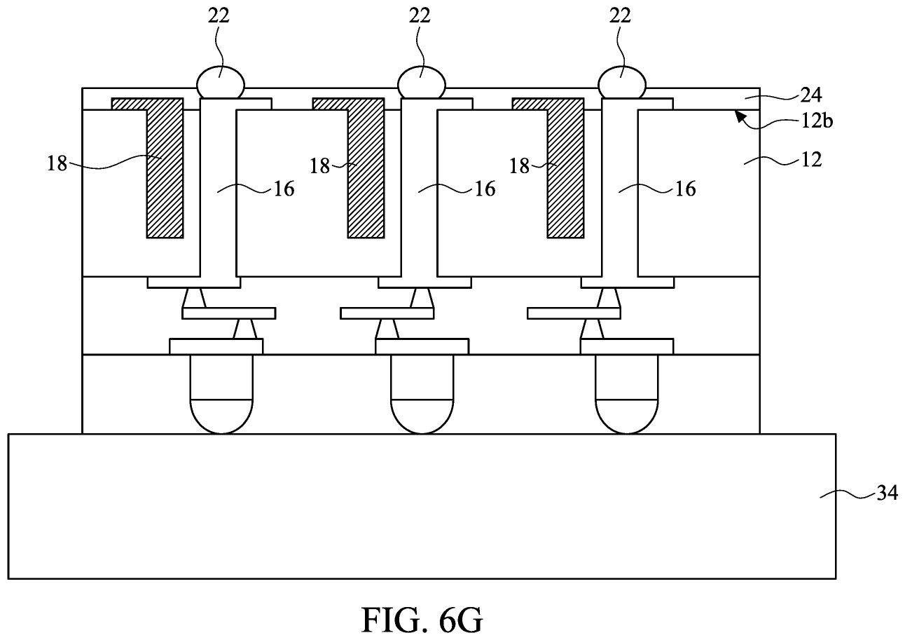

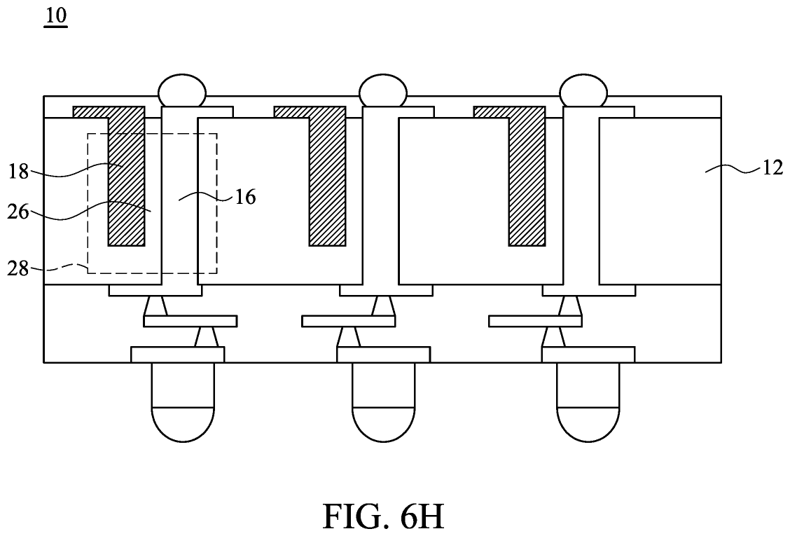

FIGS. 6A-6H are cross-sectional views of a method for fabricating a semiconductor structure. First, referring to FIG. 6A, a substrate 12 having a first side 12a and a second side 12b opposite to the first side 12a is provided. A plurality of metal structures 16 are disposed in the substrate 12. The metal structures 16 extend from the first side 12a towards the second side 12b of the substrate 12. For example, they may be pre-disposed in the substrate 12 through a through-silicon-via process. A BEOL layer 14 is disposed on the first side 12a of the substrate 12. The BEOL layer 14 includes a plurality of metal layers 14a. The metal layers 14a of different layers are connected by vias 14b filled with metal materials and electrically connected to the metal structures 16. A plurality of bumps 20 are disposed on the BEOL layer 14 and electrically connected to the metal layers 14a.

Referring to FIG. 6B, next, the substrate 12 is disposed on a carrier 34 through glue 32. As shown in FIG. 6B, the first side 12a of the substrate 12 and the carrier 34 are connected to each other through the glue 32.

Referring to FIG. 6C, next, a chemical mechanical polishing (CMP) is performed on the second side 12b of the substrate 12 until the metal structures 16 are exposed. The metal structures 16 are called frontside TSVs.

Referring to FIG. 6D, next, a patterned photoresist layer 36 is formed on the second side 12b of the substrate 12.

As shown in FIG. 6E, the substrate 12 is etched using the patterned photoresist layer 36 as a mask to form a plurality of vias 38, and the patterned photoresist layer 36 is removed. The vias 38 are disposed in the substrate 12, extend from the second side 12b towards the first side 12a of the substrate 12, and correspond to the metal structures 16.

As shown in FIG. 6F, metal material 40 is filled into the vias 38 to form a plurality of metal structures 18. In the embodiment, the metal structures 18 are called backside TSVs. The corresponding manner in which the metal structures 16 and the metal structures 18 are arranged is a single metal structure 16 corresponding to a single metal structure 18. That is, a single frontside TSV corresponds to a single backside TSV.

As shown in FIG. 6G, a plurality of bumps 22 are disposed on the metal structures 16. A RDL 24 is disposed on the second side 12b of the substrate 12 to cover the metal structures 16 and the metal structures 18, exposing the bumps 22.

As shown in FIG. 6H, the carrier 34 is removed, and the fabrication of the semiconductor structure 10 is completed. One of the metal structures 16, one of the metal structures 18, and a partial area 26 of the substrate 12 between the metal structure 16 and the metal structure 18 form a single MIM capacitor 28, for example, an embedded MIM capacitor.

In the present disclosure, embedded capacitor structures are fabricated in a wafer using TSV technology. The structure is fabricated using two TSV processes to form frontside TSVs and backside TSVs. The frontside TSV and the backside TSV can be used as an upper electrode and a lower electrode of a silicon capacitor respectively, and form a vertical embedded capacitor with the substrate sandwiched between the frontside TSV and the backside TSV. This process step can be completed together with a three-dimensional IC stacking process, which can save process steps and costs. Specifically, the process only requires that after the traditional TSV process (after forming the frontside TSVs), an additional TSV process is performed on the backside to form the backside TSVs, and then the subsequent stacking process is continued to form the frontside TSV and the backside TSV as the upper and lower electrodes of the embedded capacitor. In addition, on the backside, there are generally only TSVs for conduction, and no other traces are laid out, so the wiring is simple. Compared with fabricating the frontside TSVs, due to the complexity of the wiring on the frontside, additional copper layers are required, resulting in circuit complexity. In addition, the disclosed process can easily produce a conductive structure in which multiple semiconductor units (e.g., chips) are stacked on top of each other, thereby significantly increasing the storage space of the capacitor.

The components of several embodiments are summarized above, so that those with ordinary skill in the art can better understand various aspects of the embodiments of the present disclosure, and can easily design or modify other processes and structures based on the embodiments of the present disclosure, so as to achieve the same purposes and/or advantages as the embodiments herein. It is understood that such equivalent structures do not deviate from the spirit and scope of the embodiments of the present disclosure, and various changes, substitutions and adjustments can be made.

What is claimed is:

1. A semiconductor structure, comprising:
a substrate having a first side and a second side opposite to the first side;
a BEOL layer disposed on the first side of the substrate;
a plurality of first metal structures penetrating the substrate; and
a plurality of second metal structures disposed in the substrate, extending from the second side towards the first side of the substrate, corresponding to the first metal structures.

2. The semiconductor structure as claimed in claim 1, wherein the first metal structures and the second metal structures comprise copper.

3. The semiconductor structure as claimed in claim 1, wherein the first metal structures and the second metal structures comprise columnar structures.

4. The semiconductor structure as claimed in claim 3, wherein one of the first metal structures corresponds to one of the second metal structures.

5. The semiconductor structure as claimed in claim 3, wherein the first metal structures form an array, and the second metal structures are disposed on both sides of the array.

6. The semiconductor structure as claimed in claim 1, wherein the first metal structures comprise columnar structures, and the second metal structures comprise rectangular structures.

7. The semiconductor structure as claimed in claim 6, wherein a plurality of first metal structures correspond to one of the second metal structures.

8. The semiconductor structure as claimed in claim 1, further comprising a plurality of first bumps disposed on the BEOL layer.

9. The semiconductor structure as claimed in claim 1, further comprising a plurality of second bumps disposed on the first metal structures.

10. The semiconductor structure as claimed in claim 9, further comprising a redistribution layer disposed on the second side of the substrate to cover the first metal structures and the second metal structures, exposing the second bumps.

11. The semiconductor structure as claimed in claim 1, wherein one of the first metal structures, one of the second metal structures, and a partial area of the substrate between the first metal structure and the second metal structure form a metal-insulator-metal capacitor.

12. A semiconductor structure, comprising:
a first semiconductor unit, comprising:
a first substrate having a first side and a second side opposite to the first side;
a first BEOL layer disposed on the first side of the first substrate;
a plurality of first metal structures penetrating the first substrate; and
a plurality of second metal structures disposed in the first substrate, extending from the second side towards the first side of the first substrate, corresponding to the first metal structures; and
a second semiconductor unit electrically connected to the first semiconductor unit, wherein the second semiconductor unit comprises:
a second substrate having a first side and a second side opposite to the first side;
a second BEOL layer disposed on the first side of the second substrate;
a plurality of third metal structures penetrating the second substrate; and
a plurality of fourth metal structures disposed in the second substrate, extending from the second side towards the first side of the second substrate, corresponding to the third metal structures.

13. The semiconductor structure as claimed in claim 12, wherein the first metal structures of the first semiconductor unit are electrically connected to the third metal structures of the second semiconductor unit.

14. The semiconductor structure as claimed in claim 12, wherein one of the first metal structures, one of the second metal structures, and a partial area of the first substrate between the first metal structure and the second metal structure form a metal-insulator-metal capacitor.

15. The semiconductor structure as claimed in claim 12, wherein one of the third metal structures, one of the fourth metal structures, and a partial area of the second substrate between the third metal structure and the fourth metal structure form a metal-insulator-metal capacitor.

16. A method for fabricating a semiconductor structure, comprising:
providing a carrier with a substrate disposed thereon, the substrate having a first side and a second side opposite to the first side, wherein a BEOL layer is disposed on the first side of the substrate, and a plurality of first metal structures penetrate the substrate;
disposing a plurality of vias in the substrate, wherein the vias extend from the second side towards the first side of the substrate, and correspond to the first metal structures; and
filling metal into the vias to form a plurality of second metal structures.
